(19) United States
(12) Patent Application Publication
(10) Pub. No.: US 2024/0332106 A1
(43) Pub. Date: Oct. 3, 2024

(54) SEMICONDUCTOR DEVICE, CORRESPONDING MANUFACTURING METHOD AND SUBSTRATE FOR USE THEREIN

(71) Applicant: STMicroelectronics International N.V., Geneva (CH)

(72) Inventors: Paolo CREMA, Vimercate (IT); Alberto ARRIGONI, Eupilio (IT)

(73) Assignee: STMicroelectronics International N.V., Geneva (CH)

(21) Appl. No.: 18/614,989

(22) Filed: Mar. 25, 2024

(30) Foreign Application Priority Data
Mar. 29, 2023 (IT) 102023000006063

(51) Int. Cl. H01L 23/31; H01L 21/56; H01L 23/495

(52) U.S. Cl. CPC H01L 23/3142; H01L 21/56; H01L 23/49503

(57) ABSTRACT

A semiconductor die is arranged at a first surface of a die pad. The die pad has a peripheral edge and a second surface opposite to the first surface that includes a first region and a second region surrounding the first region. The second region extends to the peripheral edge of the die pad from a border line at the first region and includes a recessed formation extending continuously along the border line. An insulating encapsulation is molded onto the die pad with the first region of the second surface left uncovered and the second region of the second surface of the die pad being covered by the insulating encapsulation that fills the recessed formation. The recessed formation has a variable recess depth between the border line and the peripheral edge of the die pad to provide an extended length delamination path from the border line to the semiconductor die.

### PRIORITY CLAIM

This application claims the priority benefit of Italian Application for Patent No. 102023000006063 filed on Mar. 29, 2023, the content of which is hereby incorporated by reference in its entirety to the maximum extent allowable by law.

### TECHNICAL FIELD

The description relates to semiconductor devices.

One or more embodiments can be applied to semiconductor devices including integrated circuits (ICs), for instance.

### BACKGROUND

Current manufacturing processes of integrated circuit (IC) semiconductor devices comprise processing where, after molding a resin, devices are processed in an acidic bath such as a plating bath.

Adhesion between the resin and the metallic material of the leadframe may be negatively affected by exposure to such acidic baths and result in delamination of the package, especially when devices are exposed to an acidic solution for a relatively long time.

In certain cases, the degree of delamination is such that humidity and contaminants can penetrate the package and reach the semiconductor die or dice therein, possibly causing reliability issues (die corrosion or detachment, for instance).

There is a need in the art to overcome the drawbacks discussed in the foregoing.

### SUMMARY

One or more embodiments relate to an integrated circuit semiconductor device.

One or more embodiments relate to a corresponding manufacturing method.

One or more embodiments relate to a corresponding substrate such as, e.g., a leadframe for use in such a method.

Such a substrate can be provided as an intermediate product by a supplier to a manufacturer for use in manufacturing (integrated circuit) semiconductor devices.

Solutions as described herein aim at countering delamination issues by extending (lengthening) possible delamination paths between the external surface of the device and the semiconductor die/dice therein.

In solutions as described herein, longer processing of devices in an acidic bath may take place without device reliability being adversely affected thanks to possible delamination paths being made longer.

### BRIEF DESCRIPTION OF THE DRAWINGS

One or more embodiments will now be described, by way of example only, with reference to the annexed figures, wherein:

FIG. 1 is a cross-sectional view of a semiconductor device to which embodiments of the present description can apply;

FIG. 2 is exemplary of a possible aspect of a portion of a back or bottom surface of a device as illustrated in FIG. 1;

FIG. 3 is an enlarged view corresponding to the portion of FIG. 2 indicated by the arrow III;

FIG. 4 is an enlarged cross-sectional view of the portion of FIG. 1 indicated by the arrow IV; and

FIGS. 5 and 6 are cross-sectional views of the same portion of a semiconductor device showing possible embodiments of the present description applied to a device as illustrated in FIG. 1.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

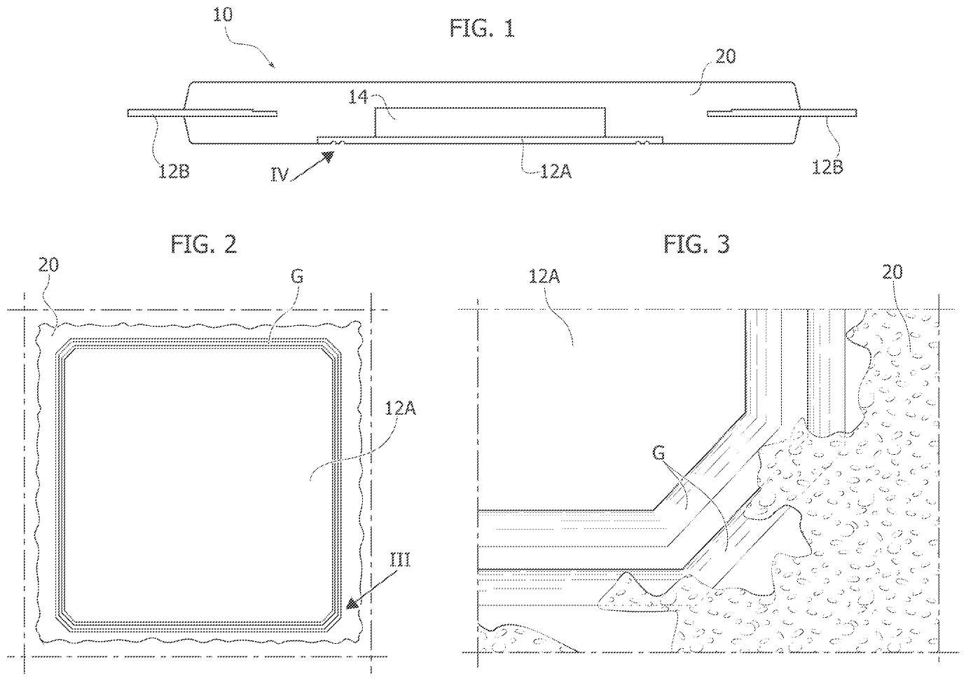

FIG. 1 illustrates a cross-sectional view of an integrated circuit (IC) semiconductor device 10.

The exemplary device 10 illustrated in FIG. 1 comprises: one or more integrated circuit dice or chips 14 (the terms chip/s and die/dice are herein regarded as synonymous) attached on a top or front surface one or more die pads 12A in a leadframe, and an array of leads 12B arranged around the die pad or pads 12A having the die or dice 14 mounted thereon.

As illustrated herein by way of example, an integrated circuit semiconductor device such as the device 10 comprises, in addition to a substrate/leadframe (that is the die pad 12A plus the leads 12B) having one or more semiconductor chips or dice 14 arranged thereon: electrically conductive formations (e.g., wires which are not visible in the figure for simplicity) that couple the semiconductor die or dice 14 to leads (outer pads) 12B in the substrate, and an insulating encapsulation 20 (e.g., an epoxy resin) molded on the assembly thus formed to complete the plastic body of the device 10.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Essentially, a leadframe comprises an array of electrically-conductive formations (or leads, e.g., 12B) that from an outline location extend inwardly in the direction of a semiconductor chip or die (e.g., 14) thus forming an array of electrically-conductive formations from a die pad (e.g., 12A) configured to have at least one integrated circuit semiconductor chip or die attached thereon. This may be via conventional means such as a die attach adhesive (a die attach film or DAF, for instance).

In current manufacturing processes of semiconductor devices, plural devices are manufactured concurrently to be separated into single individual device in a final singulation step.

For simplicity and ease of explanation, the following description will refer to manufacturing a single device.

A device 10 are exemplified herein is of a type that can be referred to as an exposed-pad quad flat package (eQFP) and the die pad 12A may be provided with a “downset” of the die pad from/between the leads 12B.

It will be appreciated that the details of the structure of a device 10 as discussed herein are merely exemplary and should not be construed in a limiting sense.

For instance, those skilled in the art may appreciated that solutions as described herein may be applied, e.g., also in case of a leadframe with a different design, including a so-called pre-molded leadframe and/or to leadframes having no downset between the die pad and the leads.

Current manufacturing processes of integrated circuit semiconductor devices 10 as illustrated in FIG. 1 include a molding step wherein, after forming electrical couplings between the chip 14 and the leads 12B (e.g., via wire bonding, not visible for simplicity) an encapsulation material 20 (e.g., an epoxy resin) is molded onto the assembly thus formed to provide a protective plastic package to the device 10.

Package reliability and durability may be negatively affected by inadequate adhesion between the metallic material (e.g., copper) of the leadframe (die pad 12A and leads 12B) and the molding compound 20 that encapsulates the device 10.

Delamination of the molding compound 20 from the die pad 12A or lead 12B may cause humidity or contaminants to enter the package (for instance, at the interface between the leadframe and the molding compound) possibly reaching the die 14 and causing failure of the device 10.

In order to enhance adhesion between the molding compound 20 and the metallic material of the die pad 12A and the leads 12B, adhesion promoters (e.g., metallic oxide-based adhesion promoters) can be provided on the die pad 12A and leads 12B.

However, adhesion promoters may be at least partly dissolved when devices 10 are processed in an acidic solution, such as a plating bath, for instance, possibly causing delamination issues.

In addition to the plating bath, other processing steps may promote delamination of the encapsulation material from the metallic material of the die pad 12A or leads 12B.

For example, processing known as “deflashing” (which involves further exposure of the device to an acidic bath) can be applied in order to remove molding compound that during the molding step has undesirably leaked and accumulated at the die pad 12A and/or on the leads 12B at the bottom/back surface of the device 10.

FIGS. 2 and 3 (where FIG. 3 is an enlarged view of the portion of FIG. 2 indicated by the arrow III) illustrate portions of the back/bottom surface of a device 10 as illustrated in FIG. 1 after a molding compound (e.g., an epoxy resin) has been molded onto the leadframe with a die 14 arranged thereon.

Such encapsulation material 20 possibly accumulated on the back/bottom surface of the die pad 12A may negatively affect the (e.g., electrical) coupling of the die pad 12A with a final substrate (e.g., a printed circuit board, PCB) onto which the device 10 is intended to be mounted.

Moreover, portions of the back/bottom surface of the die pad 12A undesirably covered with molding compound may not be plated correctly due to the presence of the molding compound 20, thus negatively affecting electrical performance and/or solderability of the device 10 on the final substrate (e.g., a PCB).

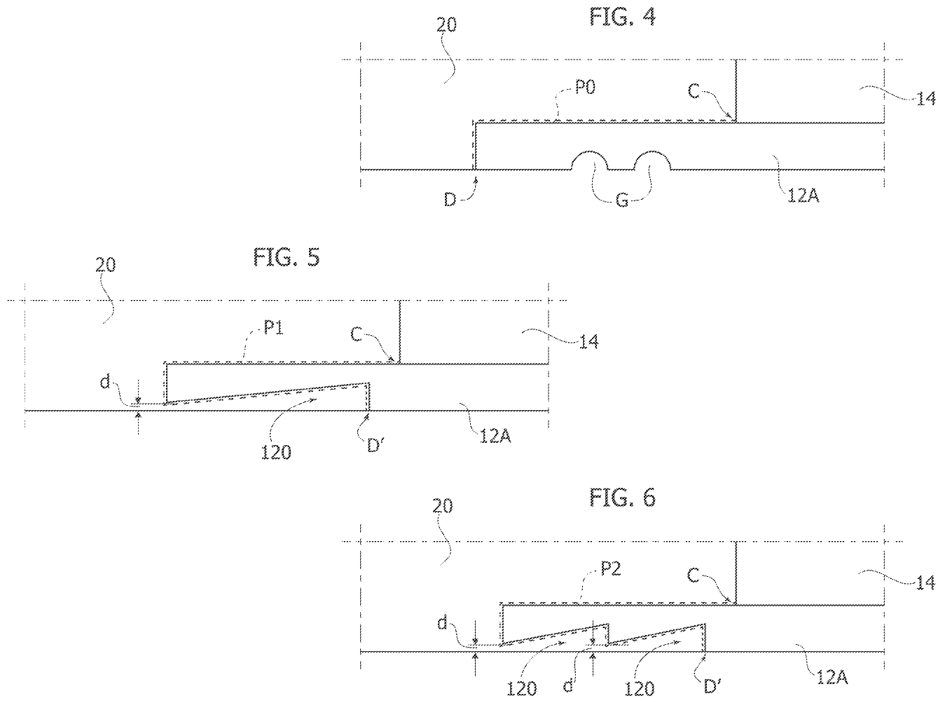

In order to counter undesired leakage of molding compound 20 over the back/bottom surface of the die pad 12A, grooves G can be provided in a conventional manner at the periphery of the die pad 12A. As visible, for instance, in FIGS. 3 and 4, two parallel grooves G can be provided at the periphery of the back/bottom surface of the die pad 12A.

FIG. 4 is an enlarged view of the portion of the conventional device 10 illustrated in FIG. 1 indicated by the arrow IV. FIG. 4 is exemplary of such a peripheral portion of the die pad 12A provided with a pair of parallel grooves G formed in the back or bottom surface of the die pad 12A in order to counter undesired leakage of molding compound 20 over the back/bottom surface of the die pad 12A.

It is noted that grooves such as the grooves G may not be completely adequate in countering undesired leakage of molding compound 20 over the bottom surface of the die pad 12A.

A deflashing step may thus be applied in order to remove excess molding compound form the die pad 12A or leads 12B. Such a deflashing step is performed as discussed in the foregoing via an acidic bath, and the acidic bath used for deflashing may undesirably cause delamination and subsequent failure of the device 10.

It is observed that delamination is more likely to start at a line D at the interface between the die pad 12A (e.g., metal such as copper) and the molding compound (e.g., resin such as an epoxy resin) that is exposed to an acidic bath (e.g., a plating or deflashing bath).

Delamination may progress from the (border) line D into the package of the device 10 along a delamination path (indicated with reference P0 in FIG. 4) possibly reaching the die 14 at a line indicated as C in FIG. 4 and causing failure of the device.

In the case of a quadrangular (e.g., square) die pad 12A and a likewise quadrangular die or chip 14 mounted thereon, the (border) line D includes four segments that extend along the sides of the die pad 12A at the back or bottom surface of the die pad 12A and the line C includes four corresponding segments that extend along the sides of the die 14 at the front or top surface of the die pad 12A.

In the following, a delamination path from a segment of the line D to an adjacent segment of the line C will be assumed in so far as a similar possible behavior may be expected to take place at any of the (four) sides of the die pad 12A and the die 14.

Delamination issues are particularly relevant when a relatively long exposure to an acidic bath (e.g., a plating bath) is envisaged. That is, exposure to an acidic bath may be long enough to cause delamination starting at a line D at the periphery of the die pad 12A at the back or bottom surface of the die pad 12A to reach the die 14 at a line C at the front or top surface of the die pad 12A, the degree of delamination depending on the exposure time.

FIGS. 2, 3 and 4 are exemplary of a conventional arrangement suffering from drawbacks as discussed previously.

As noted, these drawbacks are related to a delamination path (highlighted in dashed line and indicated as P0 in FIG. 4) that extends: from a line D at the back or bottom surface of the die pad 12A at the interface between the (e.g., metal such as copper) die pad 12A and the (e.g., plastic such as epoxy resin) molding compound 20, to the line C at the front or top surface of the die pad 12A at the interface between the molding compound 20 and the die 14.

FIGS. 5 and 6 are cross-sectional views of the same portion of an (integrated circuit) semiconductor device 10 visible in FIG. 4 showing possible embodiments of the present description.

Embodiments of the present description aim at countering delamination issues by providing an extended delamination path, namely, a (possible) delamination path that is lengthened, in other words made longer than the path P0 of FIG. 4.

That is, FIGS. 5 and 6 are again exemplary of a device 10 comprising one or more one integrated circuit semiconductor dice or chips (these terms are used herein as synonymous) 14 arranged at a first surface of a die pad 12A, the die pad 12A having a peripheral edge and a second surface opposite to the first surface.

As exemplified in FIGS. 5 and 6, the second (back or bottom) surface of the die pad 12A comprises a first (inner) region and a second (outer) region surrounding the first region.

As exemplified in FIGS. 5 and 6, the second region extends to the peripheral edge of the die pad 12A from a border line D′ bordering on the first region, with that border line D′ lying in a “backward” position (to the right in FIGS. 5 and 6) with respect to the peripheral edge of the die pad 12A.

As illustrated, that second region of the back or bottom surface of the die pad 12A comprises a recessed formation (e.g., one or more grooves) 120 that extends continuously (namely without interruption along its length) along the border line D′ to the first region. As exemplified in FIGS. 5 and 6, the insulating encapsulation 20 is molded (in manner known per se to those of skill in the art) onto the die pad 12A having the (at least one) semiconductor die 14 arranged on the first surface, with: the first, inner region of the second surface of the die pad 12A left uncovered (exposed) by the insulating encapsulation 20, and the second, outer region of the second surface of the die pad 12A covered by (namely, embedded in) the insulating encapsulation 20 with the insulating encapsulation 20 filling the recessed formation 120.

In that way, the delamination-prone interface of the (e.g., resin) encapsulation 20 to the (e.g., metal) die pad 12A is moved inwardly of the die pad 12A from the edge of the die pad (see the line D in FIG. 4) to the border line D′.

As exemplified in FIGS. 5 and 6, the recessed formation 120 has a variable recess depth between the border line D′ and the peripheral edge of the die pad 12A.

In solutions as exemplified in FIGS. 5 and 6 a longer (possible) delamination path P1, P2 is thus established from the line D′ on the back or bottom side of the die pad 12A to the line C at the periphery of the chip 14 at the front or top side of the die pad 12A.

This extended (lengthened) possible delamination path P1, P2 facilitates countering possible negative effects of processing a device such as, e.g., the device 10 in acidic baths.

In solutions as exemplified in FIGS. 5 and 6 such an extended delamination path P1, P2 (“possible” will be dropped hereinafter for brevity) is provided via a modification of the die pad design.

Such a modification essentially involves displacing more inwardly of the die pad 12A/device 10 (that is moving backward to the line D′) the delamination-prone interface between the (e.g., metal) die pad 12A and the (e.g., resin) molding compound 20 at the back or bottom surface of the die pad 12A.

This extends (lengthens) any delamination path from the line D to the line C at the periphery of the die 14 (at the front or top surface of the die pad 12A).

FIGS. 5 and 6 illustrate embodiments of the present description wherein the delamination path towards the line C is made longer by providing in the peripheral region of the die pad 12A (at the back or bottom surface thereof) recesses 120 that are positively shaped and dimensioned so that such peripheral region of the die pad 12A is extensively covered by (embedded in) the molding compound 20.

This is in contrast to the conventional approach exemplified in FIG. 4, where the grooves G are primarily intended to counter and stop (rather than facilitating) leakage of the molding compound 20 radially inwardly of the die pad 12A (towards the die or chip 14).

Recesses such as the recesses 120 in FIGS. 5 and 6 may be provided (e.g., as grooves extending continuously in a seamless manner along the sides of the—e.g., quadrangular—die pad 12A) during a leadframe/die pad formation step via stamping, for instance, or any other method known in the art.

As illustrated in FIGS. 5 and 6, at each side of the die pad 12A, a groove 120 (or two or more grooves 120 arranged side-by-side) can be provided having a right triangular cross-sectional profile (which may result in a sawtooth cross-sectional profile in the case of a formation including two or more grooves 120) extending towards the periphery of the die pad 12A starting from a line D′ that, in comparison with the line D in FIG. 4, is “moved backward” inwardly of the die pad 12A.

In contrast with the conventional approach exemplified in FIG. 4, in the solutions exemplified in FIGS. 5 and 6 the molding compound 20 is expected to penetrate and fill the grooves 120 causing the bottom surface of the device 10 to comprise: a first, inner region of the bottom surface of the die pad 12A (inwardly of the border line D′) where—at that first, inner region—the metallic material of the die pad 12A is not covered by the molding compound 20, and a second, outer region of the bottom surface of the die pad 12A, where the grooves 120 are provided, which extends (outwardly of the border line D′) to the peripheral edge of the die pad 12A where—at that second, outer region—the metallic material of the die pad 12A (i.e., the sawtooth cross-sectional profile) is completely covered by molding compound 20 molded thereon.

In both FIGS. 5 and 6 the delamination path P1, P2 will thus include, in addition to a portion substantially corresponding to the delamination path P0 from the line D to the line C of FIG. 4, an “extension” (resulting from the interface between the die pad 12A and the molding compound 20 being moved from the line D to the line D′) determined by the cross-sectional profile of the recess or recesses 120.

As discussed previously, when exposing a device 10 as illustrated in FIG. 5 or 6 to an acidic bath, delamination may first start at the line D′, namely at the (delamination-prone) interface between the metallic material (e.g., copper) of the die pad 12A and the molding compound 20 that is exposed to the acidic bath.

Recesses such as the grooves 120 provided in the peripheral region of the die pad 12A (covered by the molding compound 20) increase the length of the delamination path from P0 (as highlighted in FIG. 4) to values P1>P0 (FIG. 5) or P2>P0 (FIG. 6).

As illustrated, the grooves 120 have a cross-sectional profile (essentially a depth) sized and dimensioned such that at the second, outer region of its bottom surface the die pad 12A is completely embedded in the molding compound 20, with no metal from the die pad 12A exposed at the surface of the molding compound at the bottom surface of the die pad 12A in the second, outer region. In other words, there is an offset gap d between the planar back surface of the die pad 12A and any projection of the cross-sectional profile in the second, outer region.

This is exemplified in FIGS. 5 and 6 by a gap d that separates from the outer surface of the molding material 20 the portions of the die pad 12A that come closer to that surface in the second, outer region of the bottom surface of the die pad 12A.

It will be appreciated that this arrangement does not merely result in the second, outer region forming an undercut at the bottom surface the die pad 12A.

The, e.g., sawtooth, cross-sectional profile of the recess or recesses 120 will result in these recesses having a recess depth variable between the line D′ and the peripheral edge of the die pad 12A at the back or bottom side of the die pad 12A.

Such a cross-sectional profile of the recesses 120 will result in a delamination path starting from the line D′ and having a meandered (e.g., zig-zag) pattern. That pattern will bestow on the extended delamination path a length longer that the length that would result for such a delamination path in the case of an undercut at the bottom surface of the die pad 12A having a rectangular cross-section, namely a constant, non-variable recess depth between the line D′ and the peripheral edge of the die pad 12A.

In FIG. 5, a single variable-depth recess 120 having a triangular cross-sectional profile is formed in the second (outer) region of the bottom surface of the die pad 12A, providing the delamination path indicated as P1 in FIG. 5.

In FIG. 6, plural variable-depth recesses 120 having triangular cross-sectional profiles are shown formed in the second (outer) region of the bottom surface of the die pad 12A, resulting in a sawtooth cross-sectional profile that provides an even longer delamination path P2 (P2>P1>P0).

As illustrated in FIGS. 5 and 6, the recess or recesses 120 are provided with a variable depth. A variable depth has the effect of further increasing the length of the delamination path (compared to constant depth recesses) thus further extending allowable exposure time to an acidic bath.

The particular shapes of the recesses illustrated in FIGS. 5 and 6 are merely exemplary in as much as differently shaped recesses may be formed. For instance, in the place of a triangular or sawtooth profile, trapezoidal, square-wave or chirp-waveform cross-sectional profiles can be adopted for the recess or recesses 120.

To summarize, in solutions as exemplified in FIGS. 5 and 6, the insulating encapsulation 20 is molded onto the die pad 12A having the semiconductor die 14 arranged on the first surface, leaving the first (inner) region of the second surface of the die pad 12A uncovered by the insulating encapsulation 20 while the second (outer) region of the second surface of the die pad 12A is covered by the insulating encapsulation 20 that fills the recessed formation 120. Stated otherwise, the insulating encapsulation 20 covers and embeds the second region of the die pad 12A.

In that way, the delamination-prone interface of the encapsulation to the die pad 12A is moved “backward” to the border line D′.

The recessed formation (e.g., one or more grooves) 120 has a variable recess depth between the border line D′ and the peripheral edge of the die pad 12A to provide an extended length of any possible delamination path (D′ to C) from the border line D′ to the semiconductor die 14.

As discussed previously, recesses are provided with a variable depth in order to increase the length of the delamination path. A longer delamination path (such as P1 or P2 illustrated in FIGS. 5 and 6, respectively) facilitates longer processing of semiconductor devices in an acidic bath (e.g., a plating or deflashing acidic bath) effectively countering undesired effects on (e.g., reliability) of the package and the device 10.

Moreover, recessed sculptured formations such as the grooves 120 exemplified in FIGS. 5 and 6 have a beneficial anchoring effect of the encapsulation 20 to the substrate (leadframe) that comprises the die pad 12A.

As discussed, the recessed formation comprises at least one groove 120 extending continuously (without interruptions along its length) along the border line D′ to the first region (opposite the portion of the front or top surface of the die pad 12A where the chip or die 14 is attached.

Advantageously, the recessed formation comprises a plurality of grooves 120 extending continuously and side-by-side along the border line D′ to the first region.

By way of example the recessed formation 120 may comprise one or more triangular cross-sectional profiles from the border line D′ to the peripheral edge of the die pad 12A.

In certain embodiments, the recessed formation 120 may comprise a plurality of grooves 120 extending side-by-side along the border line D′, with these grooves 120 having (each) a triangular cross-sectional profile wherein the resulting recessed formation has a sawtooth cross-sectional profile from the border line D′ to the peripheral edge of the die pad 12A.

Advantageously, as exemplified in FIGS. 5 and 6, the recessed formation 120 (e.g., each of a plurality of grooves extending side-by-side) has a decreasing recess depth from the border line D′ to the peripheral edge of the die pad 12A.

Without prejudice to the underlying principles, the details and the embodiments may vary, even significantly, with respect to what has been described by way of example only without departing from the scope of the embodiments.

The claims are an integral part of the technical teaching provided in respect of the embodiments.

The extent of protection is determined by the annexed claims.

1. A device, comprising:
a semiconductor die arranged at a first surface of a die pad, the die pad having a peripheral edge and a second surface opposite to the first surface, the second surface of the die pad comprising a first region and a second region surrounding the first region, wherein the second region extends from a border line at the first region to the peripheral edge of the die pad and comprises a recessed formation extending continuously along the border line at the first region; and
an insulating encapsulation molded onto the die pad having the at least one semiconductor die arranged on the first surface, wherein the first region of the second surface of the die pad is left uncovered by the insulating encapsulation and the second region of the second surface of the die pad is covered by the insulating encapsulation;
wherein the insulating encapsulation fills the recessed formation with a pad-to-encapsulation interface at said border line; and
wherein the recessed formation has a variable recess depth between said border line and the peripheral edge of the die pad.

2. The device of claim 1, wherein the recessed formation comprises at least one groove extending continuously along the border line.

3. The device of claim 1, wherein the recessed formation comprises a plurality of grooves extending side-by-side along the border line.

4. The device of claim 1, wherein the recessed formation comprises at least one triangular cross-sectional profile from said border line to the peripheral edge of the die pad.

5. The device of claim 1, wherein the recessed formation comprises a plurality of grooves extending side-by-side along the border line, each groove of the plurality of grooves having a triangular cross-sectional profile; and wherein the triangular cross-sectional profiles of the groove for the recessed formation define a sawtooth cross-sectional profile from said border line to the peripheral edge of the die pad.

6. The device of claim 1, wherein the recessed formation has a decreasing recess depth from said border line to the peripheral edge of the die pad.

7. A method, comprising:
arranging at least one semiconductor die at a first surface of a die pad, the die pad having a peripheral edge and a second surface opposite to the first surface, the second surface of the die pad comprising a first region and a second region surrounding the first region, wherein the second region extends from a border line at the first region to the peripheral edge of the die pad and comprises a recessed formation extending continuously along the border line at the first region; and
molding an insulating encapsulation onto the die pad having the at least one semiconductor die arranged on the first surface, wherein the insulating encapsulation leaves the first region of the second surface of the die pad uncovered by the insulating encapsulation and covers the second region of the second surface of the die pad;
wherein the insulating encapsulation fills the recessed formation and provides a pad-to-encapsulation interface at said border line; and
wherein the recessed formation has a variable recess depth between said border line and the peripheral edge of the die pad.

8. The method of claim 7, wherein the recessed formation comprises at least one groove extending continuously along the border line.

9. The method of claim 7, wherein the recessed formation comprises a plurality of grooves extending side-by-side along the border line.

10. The method of claim 7, wherein the recessed formation comprises at least one triangular cross-sectional profile from said border line to the peripheral edge of the die pad.

11. The method of claim 7, wherein the recessed formation comprises a plurality of grooves extending side-by-side along the border line, each groove of the plurality of grooves having a triangular cross-sectional profile; and wherein the triangular cross-sectional profiles of the groove for the recessed formation define a sawtooth cross-sectional profile from said border line to the peripheral edge of the die pad.

12. The method of claim 7, wherein the recessed formation has a decreasing recess depth from said border line to the peripheral edge of the die pad.

13. A substrate for use in manufacturing semiconductor devices, the substrate comprising:
die pad having a first surface, a peripheral edge and a second surface opposite to the first surface, the second surface of the die pad comprising a first region and a second region surrounding the first region, wherein the second region extends from a border line at the first region to the peripheral edge of the die pad and comprises a recessed formation extending continuously along the border line at the first region;
wherein the recessed formation has a variable recess depth between said border line and the peripheral edge of the die pad.

14. The substrate of claim 13, wherein:
the recessed formation comprises at least one groove extending continuously along the border line to the first region.

15. The substrate of claim 13, wherein:
the recessed formation comprises at least one triangular cross-sectional profile from said border line to the peripheral edge of the die pad.

16. The substrate of claim 13, wherein:
the recessed formation has a decreasing recess depth from said border line to the peripheral edge of the die pad.

17. A device, comprising:
a die pad having a first surface, a peripheral edge and a second surface opposite to the first surface;
a semiconductor die arranged at the first surface of the die pad;
wherein the second surface includes a recessed formation comprising a plurality of grooves extending side-by-side parallel to the peripheral edge, each groove of the plurality of grooves having a right triangular cross-sectional profile;
wherein the triangular cross-sectional profiles of the grooves define a sawtooth cross-sectional profile extending inwardly from the peripheral edge of the die pad; and
an insulating encapsulation molded onto the semiconductor die and the die pad, said insulating encapsulation completely covering the sawtooth cross-sectional profile.
